(19) United States
(12) Patent Application Publication
(10) Pub. No.: US 2025/0246530 A1
(43) Pub. Date: Jul. 31, 2025

(54) CHIP PACKAGE AND MANUFACTURING METHOD THEREOF

(71) Applicant: Xintec Inc., Taoyuan City (TW)

(72) Inventors: Wei-Luen SUEN, Taoyuan City (TW); Po-Jung CHEN, Yunlin County (TW); Chia Ming CHENG, New Taipei City (TW); Po-Shen LIN, Taoyuan City (TW); Jiun-Yen LAI, Taoyuan City (TW); Tsang-Yu LIU, Zhubei City (TW)

(21) Appl. No.: 19/015,618

(22) Filed: Jan. 9, 2025

Related U.S. Application Data
(60) Provisional application No. 63/627,635, filed on Jan. 31, 2024.

(51) Int. Cl. H01L 23/498; H01L 21/48; H01L 21/56; H01L 23/00; H01L 23/31; H01L 23/48; H01L 25/16; H10D 80/30

(52) U.S. Cl. CPC H01L 23/49833; H01L 21/4846; H01L 21/565; H01L 23/481; H01L 23/49838; H01L 24/16; H01L 24/32; H01L 24/73; H01L 25/16; H01L 23/3107; H01L 2224/16225; H01L 2224/32145; H01L 2224/32225; H01L 2224/73204; H01L 2224/73253; H01L 2225/06513; H01L 2225/06544; H01L 2225/06568; H01L 2924/1433; H01L 2924/1461; H10D 80/30

(57) ABSTRACT

A chip package includes a mother chip, a daughter chip, a molding compound, a first redistribution layer, and a second redistribution layer. The daughter chip is located on a first surface of the mother chip. The molding compound covers the mother chip and the daughter chip, and the daughter chip is surrounded by the molding compound. The first redistribution layer is located on the first surface of the mother chip and is covered by the molding compound. The second redistribution layer is electrically connected to the first redistribution layer, and is located on one of a second surface of the mother chip and a surface of the molding compound. One of the first redistribution layer and the second redistribution layer is electrically connected to the daughter chip, and the other is electrically connected to the mother chip.

### CROSS-REFERENCE TO RELATED APPLICATION

This application claims priority to U.S. Provisional Application Ser. No. 63/627,635, filed Jan. 31, 2024, which is herein incorporated by reference.

### BACKGROUND

### Field of Invention

The present disclosure relates to a chip package and a manufacturing method of the chip package.

### Description of Related Art

Generally speaking, a conventional chip package may include plural semiconductor chips with different functions. For example, a daughter chip may be stacked on a mother chip, and a bonding wire is used to connect the mother chip and an underlying printed circuit board (PCB) or an electrode plate. Alternatively, two chips may be laterally disposed on one surface of the printed circuit board, or respectively disposed on two opposite surfaces of the printed circuit board.

However, the aforesaid chip packages have disadvantages of high cost, large dimension, transmission latency, and extra substrate (e.g., PCB) need.

### SUMMARY

According to some embodiments of the present disclosure, a chip package includes a mother chip, a daughter chip, a molding compound, a first redistribution layer, and a second redistribution layer. The daughter chip is located on a first surface of the mother chip. The molding compound covers the mother chip and the daughter chip, and the daughter chip is surrounded by the molding compound. The first redistribution layer is located on the first surface of the mother chip and is covered by the molding compound. The second redistribution layer is electrically connected to the first redistribution layer, and is located on one of a second surface of the mother chip opposite to the first surface and a surface of the molding compound that faces away from the mother chip and the daughter chip. One of the first redistribution layer and the second redistribution layer is electrically connected to the daughter chip, and the other of the first redistribution layer and the second redistribution layer is electrically connected to the mother chip.

In some embodiments, the daughter chip has a micro bump located on the first surface of the mother chip and electrically connected to the first redistribution layer.

In some embodiments, the chip package further includes an underfill layer located between the daughter chip and the mother chip and surrounding the micro bump.

In some embodiments, the chip package further includes a passivation layer located between the underfill layer and the mother chip.

In some embodiments, the chip package further includes a conductive pillar located on the first redistribution layer and surrounded by the molding compound, wherein two ends of the conductive pillar are respectively in electrical contact with the first redistribution layer and the second redistribution layer.

In some embodiments, the chip package further includes a conductive pillar located on a surface of the daughter chip facing away from the mother chip, and electrically connected to the second redistribution layer and surrounded by the molding compound.

In some embodiments, the mother chip has a through hole and a conductive pad in the through hole, and the second redistribution layer extends into the through hole and is in electrical contact with the conductive pad.

In some embodiments, the through hole is tapered from the second surface of the mother chip to the conductive pad.

In some embodiments, the through hole is tapered from the first surface of the mother chip to the conductive pad.

In some embodiments, the chip package further includes a die attach film located between the daughter chip and the mother chip.

In some embodiments, the chip package further includes a passivation layer located between the die attach film and the mother chip.

In some embodiments, the chip package further includes a first passivation layer located on the second redistribution layer and the second surface of the mother chip.

In some embodiments, the chip package further includes a conductive structure located on the second redistribution layer and in the first passivation layer.

In some embodiments, the chip package further includes a second passivation layer located between the second redistribution layer and the first passivation layer.

In some embodiments, the chip package further includes a first passivation layer located on the second redistribution layer and the surface of the molding compound that faces away from the mother chip and the daughter chip.

In some embodiments, the chip package further includes a conductive structure located on the second redistribution layer and in the first passivation layer.

In some embodiments, the chip package further includes a second passivation layer located between the second redistribution layer and the surface of the molding compound.

In some embodiments, the second surface of the mother chip has an image sensing region.

In some embodiments, the chip package further includes a micro bump located on the second surface of the mother chip.

According to some embodiments of the present disclosure, a manufacturing method of a chip package includes forming a first redistribution layer on a first surface of a mother chip; disposing a daughter chip on the first surface of the mother chip; forming a molding compound covering the mother chip and the daughter chip, wherein the daughter chip is surrounded by the molding compound, and the first redistribution layer is covered by the molding compound; and forming a second redistribution layer electrically connected to the first redistribution layer and on one of a second surface of the mother chip opposite to the first surface and a surface of the molding compound that faces away from the mother chip and the daughter chip, wherein one of the first redistribution layer and the second redistribution layer is electrically connected to the daughter chip, and the other of the first redistribution layer and the second redistribution layer is electrically connected to the mother chip.

In the aforementioned embodiments of the present disclosure, since the first redistribution layer is located on the first surface of the mother chip and is covered by the molding compound, and the second redistribution layer is electrically connected to the first redistribution layer and is located on one of the second surface of the mother chip and the surface of the molding compound, the chip package including the stacked mother chip and daughter chip does not require any bonding wire and printed circuit board (PCB) for connection and support. As a result, the chip package has advantages of low cost, small dimension, low transmission latency, and no substrate (e.g., PCB) need.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a chip package according to one embodiment of the present disclosure.

FIG. 2 is a cross-sectional view at an intermediate stage of a manufacturing method of the chip package of FIG. 1.

FIG. 3 is a cross-sectional view of a chip package according to one embodiment of the present disclosure.

FIG. 4 is a cross-sectional view at an intermediate stage of a manufacturing method of the chip package of FIG. 3.

FIG. 5 is a cross-sectional view of a chip package according to one embodiment of the present disclosure.

FIG. 6 is a cross-sectional view at an intermediate stage of a manufacturing method of the chip package of FIG. 5.

FIG. 7 is a cross-sectional view of a chip package according to one embodiment of the present disclosure.

FIG. 8 is a cross-sectional view at an intermediate stage of a manufacturing method of the chip package of FIG. 7.

FIGS. 9 to 26 are cross-sectional views of chip packages according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

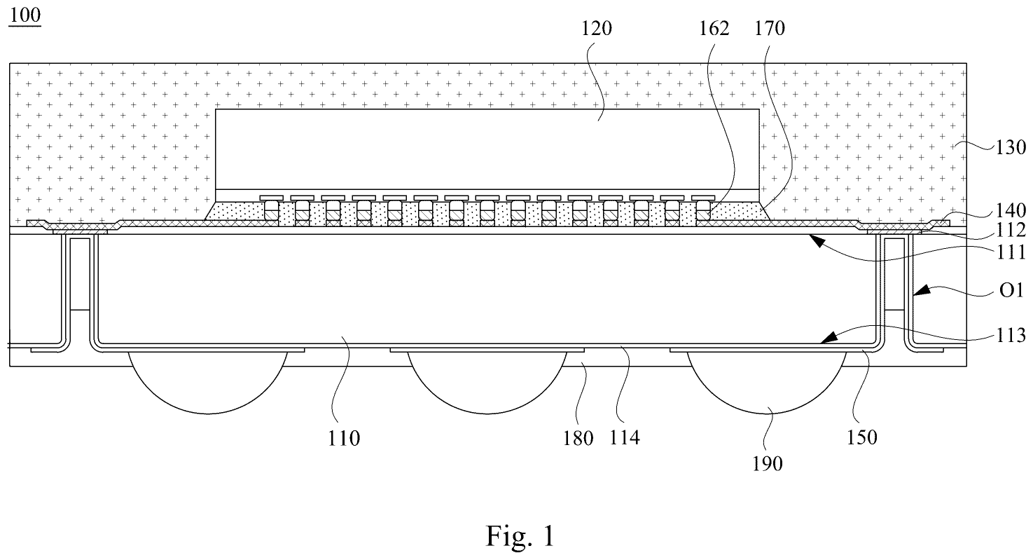

FIG. 1 is a cross-sectional view of a chip package 100 according to one embodiment of the present disclosure. The chip package 100 includes a mother chip 110, a daughter chip 120, a molding compound 130, a first redistribution layer 140, and a second redistribution layer 150. The daughter chip 120 is located on a first surface 111 of the mother chip 110. The molding compound 130 covers the mother chip 110 and the daughter chip 120, and the daughter chip 120 is surrounded by the molding compound 130. The first redistribution layer 140 is located on the first surface 111 of the mother chip 110 and is covered by the molding compound 130. The second redistribution layer 150 is electrically connected to the first redistribution layer 140, and is located on a second surface 113 of the mother chip 110, in which the second surface 113 is opposite to the first surface 111. The first redistribution layer 140 is electrically connected to the daughter chip 120, and the second redistribution layer 150 is electrically connected to the mother chip 110.

In some embodiments, the daughter chip 120 may be a micro-electromechanical systems (MEMS) chip, and the mother chip 110 may be an application specific integrated circuit (ASIC) chip. The material of each of the daughter chip 120 and the mother chip 110 may include silicon. The mother chip 110 has a through hole O1 and a conductive pad 112 (e.g., a landing pad) in the through hole O1, and the second redistribution layer 150 extends into the through hole O1 and is in electrical contact with the conductive pad 112. The first redistribution layer 140 extends onto the conductive pad 112. The daughter chip 120 has a micro bump 162 located on the first surface 111 of the mother chip 110, and the micro bump 162 is electrically connected to the first redistribution layer 140. Therefore, the daughter chip 120 can be electrically connected to the mother chip 110. In some embodiments, the material of each of the first redistribution layer 140 and the second redistribution layer 150 may include titanium and copper, and the material of micro bump 162 may include copper, tin, and silver.

Specifically, since the first redistribution layer 140 is located on the first surface 111 of the mother chip 110 and is covered by the molding compound 130, and the second redistribution layer 150 is electrically connected to the first redistribution layer 140 and is located on the second surface 113 of the mother chip 110, the chip package 100 including the stacked mother chip 110 and daughter chip 120 does not require any bonding wire and printed circuit board (PCB) for connection and support. As a result, the chip package 100 has advantages of low cost, small dimension, low transmission latency, and no substrate (e.g., PCB) need.

Moreover, the chip package 100 further includes an underfill layer 170 located between the daughter chip 120 and the mother chip 110, and the underfill layer 170 surrounds the micro bump 162. In some embodiments, the mother chip 110 has an isolation layer 114 on the second surface 113 and the sidewall of the through hole 01. The chip package 100 further includes a first passivation layer 180 and a conductive structure 190 (e.g., a solder ball). The first passivation layer 180 is located on the second redistribution layer 150 and the second surface 113 of the mother chip 110. The conductive structure 190 is located on the second redistribution layer 150 and in the first passivation layer 180. The material of the first passivation layer 180 may include solder mask or polyimide (PI).

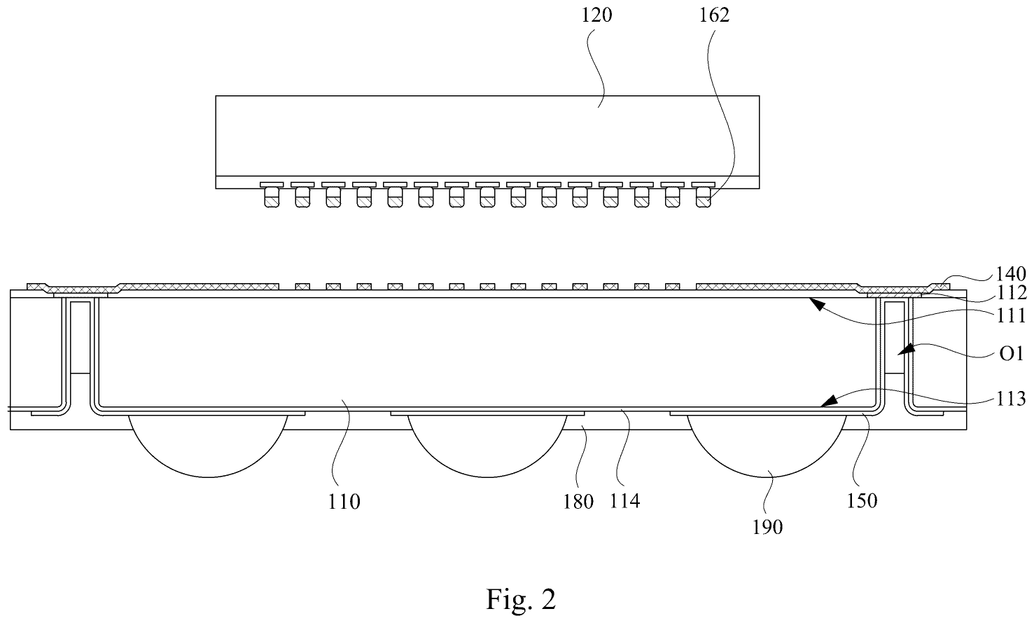

FIG. 2 is a cross-sectional view at an intermediate stage of a manufacturing method of the chip package 100 of FIG. 1. As shown in FIG. 1 and FIG. 2, the manufacturing method of the chip package 100 includes forming the first redistribution layer 140 on the first surface 111 of the mother chip 110; forming the second redistribution layer 150 electrically connected to the first redistribution layer 140 and on the second surface 113 of the mother chip 110, wherein the first redistribution layer 140 is electrically connected to the daughter chip 120, and the second redistribution layer 150 is electrically connected to the mother chip 110; disposing the daughter chip 120 on the first surface 111 of the mother chip 110; and forming the molding compound 130 covering the mother chip 110 and the daughter chip 120, wherein the daughter chip 120 is surrounded by the molding compound 130, and the first redistribution layer 140 is covered by the molding compound 130.

It is to be noted that the connection relationships, the materials, and the advantages of the elements described above will not be repeated in the following description. In the following description, other types of chip packages will be explained.

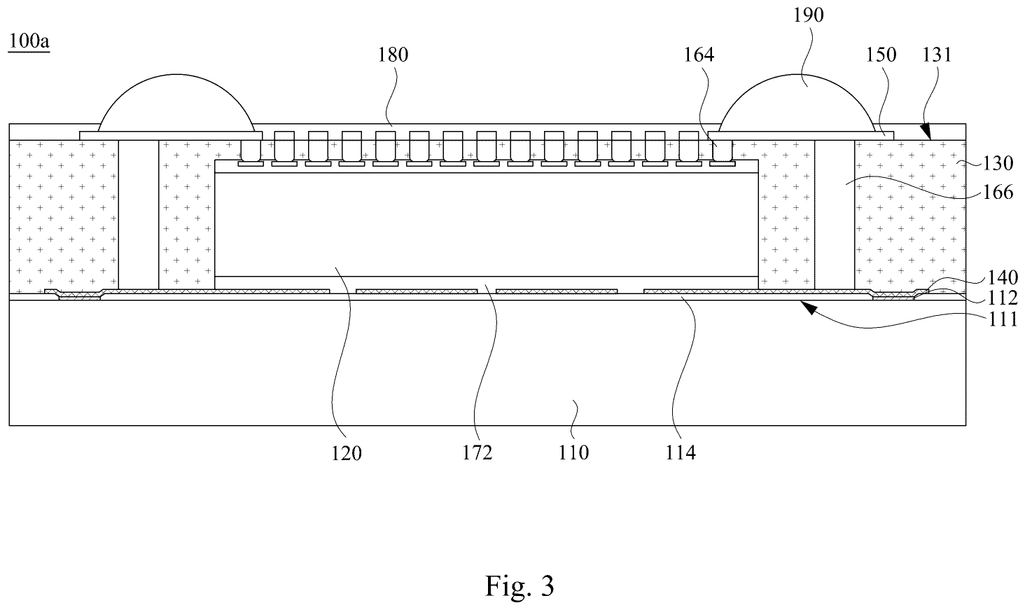

FIG. 3 is a cross-sectional view of a chip package 100a according to one embodiment of the present disclosure. The difference between this embodiment and the embodiment of FIG. 1 is that the second redistribution layer 150 of the chip package 100a is located on a surface 131 of the molding compound 130 that faces away from the mother chip 110 and the daughter chip 120. Moreover, the chip package 100a further includes a conductive pillar 164 and a conductive pillar 166. The conductive pillar 164 is located on the surface of the daughter chip 120 facing away from the mother chip 110, and is electrically connected to the second redistribution layer 150 and surrounded by the molding compound 130. The conductive pillar 166 is located on the first redistribution layer 140 and surrounded by the molding compound 130, wherein two ends of the conductive pillar 166 are respectively in electrical contact with the first redistribution layer 140 and the second redistribution layer 150. Accordingly, the second redistribution layer 150 is electrically connected to the daughter chip 120, and the first redistribution layer 140 is electrically connected to the mother chip 110. In some embodiments, the chip package 100a further includes a die attach film 172 located between the daughter chip 120 and the mother chip 110. Moreover, the chip package 100a further includes the conductive structure 190 located on the second redistribution layer 150 and in the first passivation layer 180.

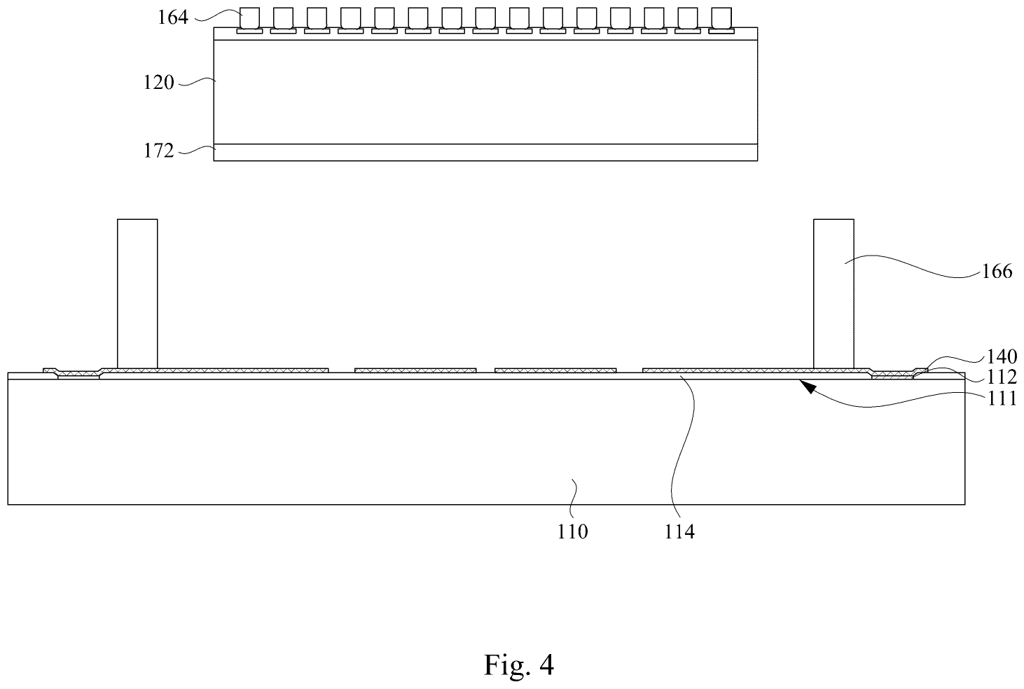

FIG. 4 is a cross-sectional view at an intermediate stage of a manufacturing method of the chip package 100a of FIG. 3. As shown in FIG. 3 and FIG. 4, the manufacturing method of the chip package 100a includes forming the first redistribution layer 140 on the first surface 111 of the mother chip 110; forming the conductive pillar 166 on the first redistribution layer 140; forming the conductive pillar 164 on the daughter chip 120; disposing the daughter chip 120 on the first surface 111 of the mother chip 110; forming the molding compound 130 covering the mother chip 110 and the daughter chip 120; and forming the second redistribution layer 150 on the surface 131 of the molding compound 130, the conductive pillar 164, and the conductive pillar 166.

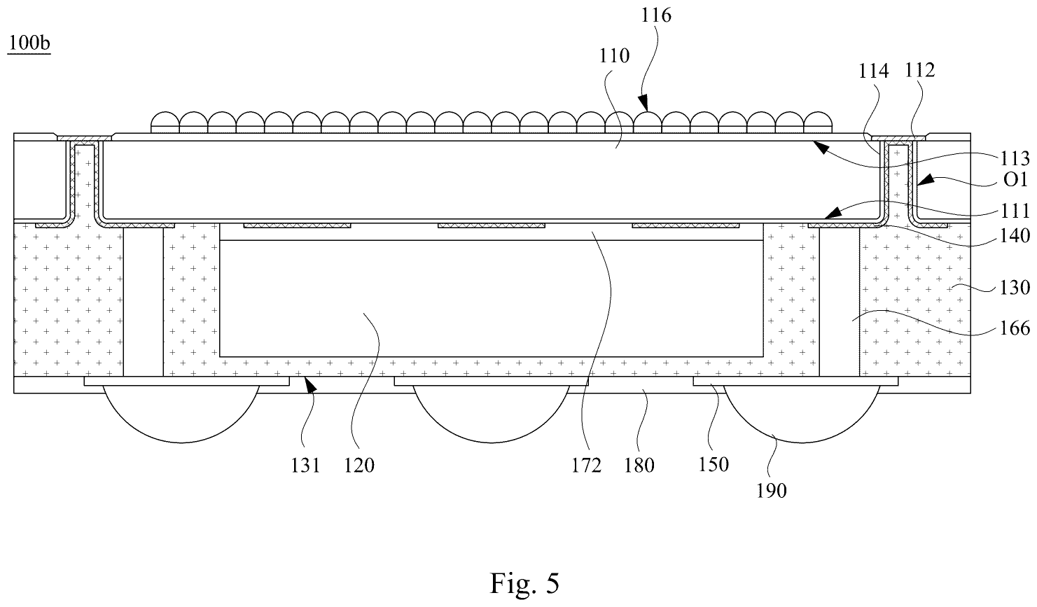

FIG. 5 is a cross-sectional view of a chip package 100b according to one embodiment of the present disclosure. The difference between this embodiment and the embodiment of FIG. 1 is that the daughter chip 120 and the molding compound 130 of the chip package 100b are located below the mother chip 110, the second redistribution layer 150 is located on the surface 131 of the molding compound 130, the chip package 100b further includes the conductive pillar 166, and the second surface 113 of the mother chip 110 has an image sensing region 116. In this embodiment, the mother chip 110 may be a CMOS image sensor (CIS), and the daughter chip 120 may be an image signal processor (ISP). The conductive pillar 166 is located in the molding compound 130 and electrically connected to the first redistribution layer 140 and the second redistribution layer 150. In addition, the chip package 100b includes the die attach film 172 located between the daughter chip 120 and the mother chip 110.

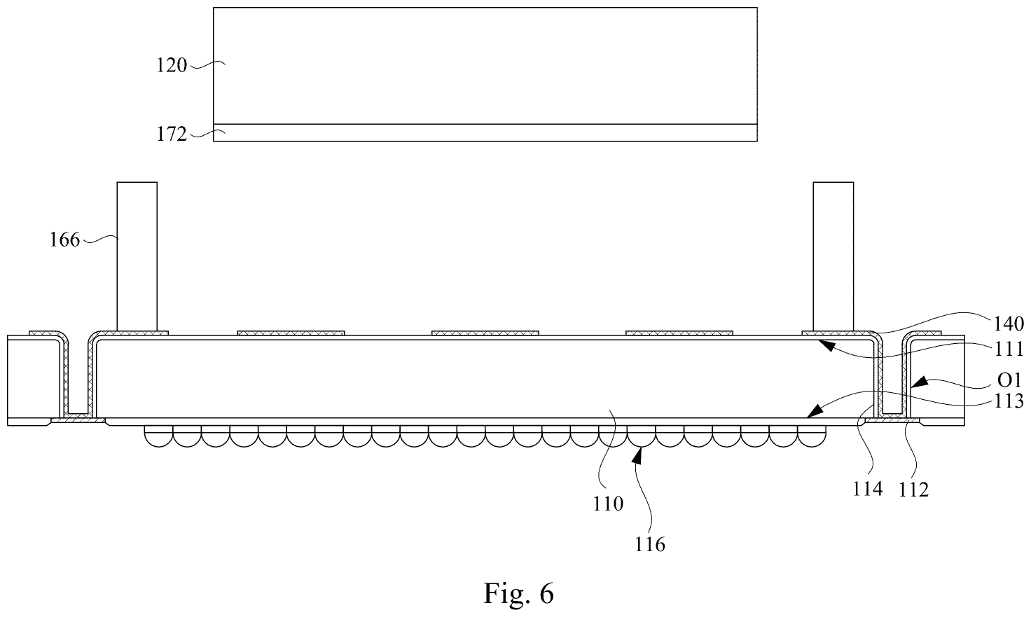

FIG. 6 is a cross-sectional view at an intermediate stage of a manufacturing method of the chip package 100b of FIG. 5. As shown in FIG. 5 and FIG. 6, the manufacturing method of the chip package 100b includes forming the first redistribution layer 140 on the first surface 111 of the mother chip 110; forming the conductive pillar 166 on the first redistribution layer 140; disposing the daughter chip 120 on the first surface 111 of the mother chip 110; forming the molding compound 130 covering the mother chip 110 and the daughter chip 120; and forming the second redistribution layer 150 on the surface 131 of the molding compound 130 and the conductive pillar 166, such that the second redistribution layer 150 is electrically connected to the first redistribution layer 140.

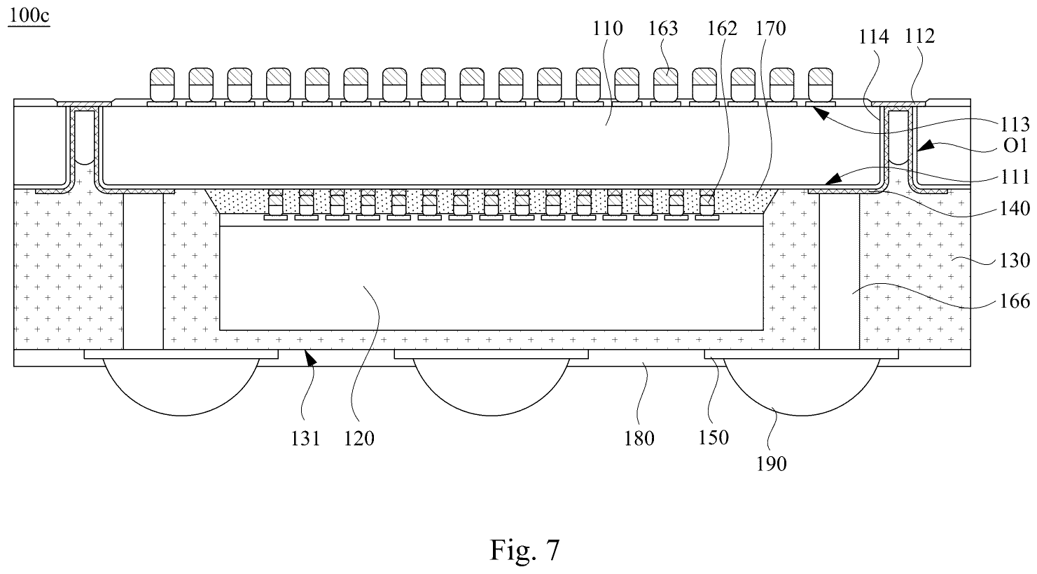

FIG. 7 is a cross-sectional view of a chip package 100c according to one embodiment of the present disclosure. The difference between this embodiment and the embodiment of FIG. 5 is that the daughter chip 120 of the chip package 100c has the micro bump 162 located on the first surface 111 of the mother chip 110, and the chip package 100c has a micro bump 163 located on the second surface 113 of the mother chip 110. Moreover, the chip package 100 further includes the underfill layer 170 located between the daughter chip 120 and the mother chip 110, and the underfill layer 170 surrounds the micro bump 162. In this embodiment, the chip package 100c may be a high voltage device with dual side connection.

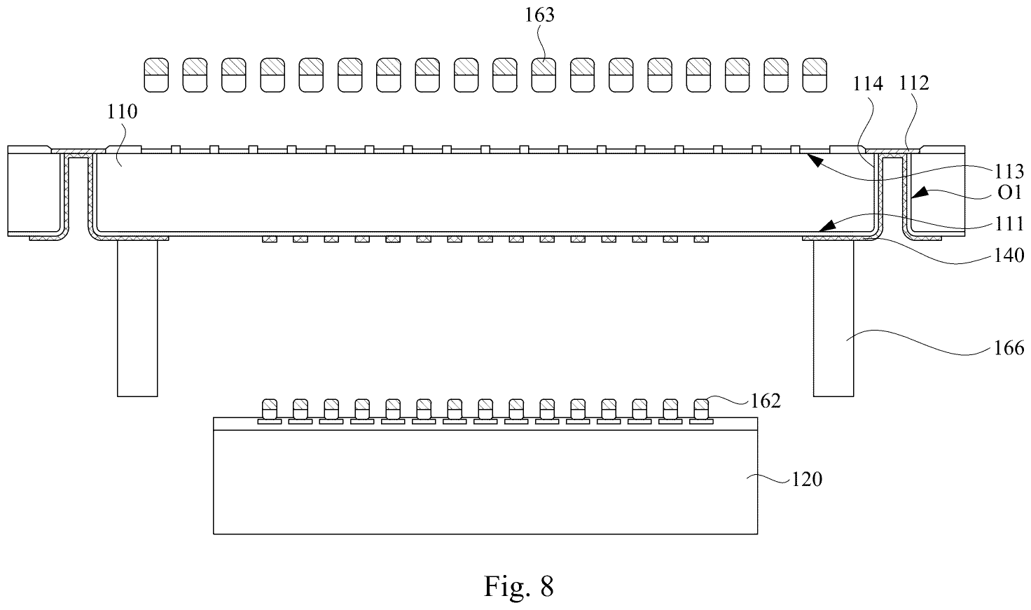

FIG. 8 is a cross-sectional view at an intermediate stage of a manufacturing method of the chip package 100c of FIG. 7. As shown in FIG. 7 and FIG. 8, the manufacturing method of the chip package 100c includes forming the first redistribution layer 140 on the first surface 111 of the mother chip 110; forming the conductive pillar 166 on the first redistribution layer 140; forming the micro bump 163 on the second surface 113 of the mother chip 110; disposing the daughter chip 120 on the first surface 111 of the mother chip 110; forming the molding compound 130 covering the mother chip 110 and the daughter chip 120; and forming the second redistribution layer 150 on the surface 131 of the molding compound 130 and the conductive pillar 166, such that the second redistribution layer 150 is electrically connected to the first redistribution layer 140.

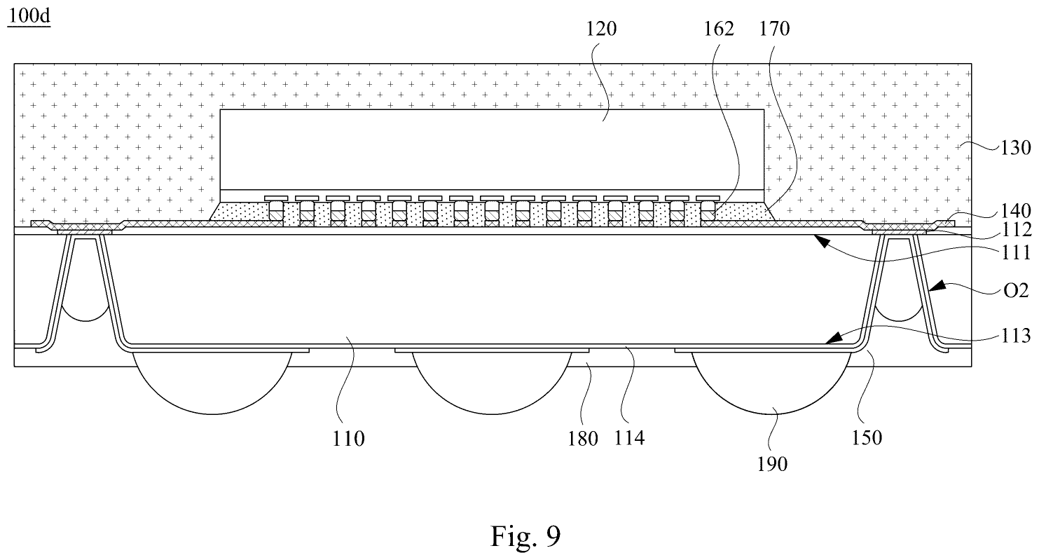

FIGS. 9 to 26 are cross-sectional views of chip packages 100d-100u according to some embodiments of the present disclosure. As shown in FIG. 9, the difference between this embodiment and the embodiment of FIG. 1 is that the mother chip 110 of the chip package 100d has a through hole O2 that is tapered from the second surface 113 of the mother chip 110 to the conductive pad 112.

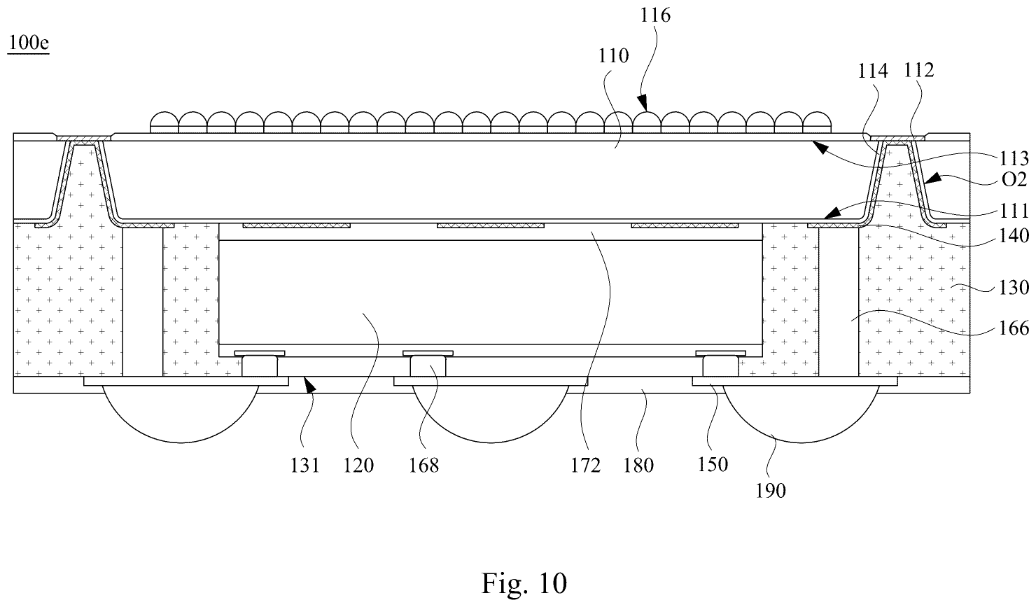

As shown in FIG. 10, the difference between this embodiment and the embodiment of FIG. 5 is that the mother chip 110 of the chip package 100e has the through hole O2 that is tapered from the second surface 113 of the mother chip 110 to the conductive pad 112. Furthermore, the chip package 100e further includes a conductive pillar 168 electrically connected to the daughter chip 120 and the second redistribution layer 150, and the conductive pillar 168 is surrounded by the molding compound 130.

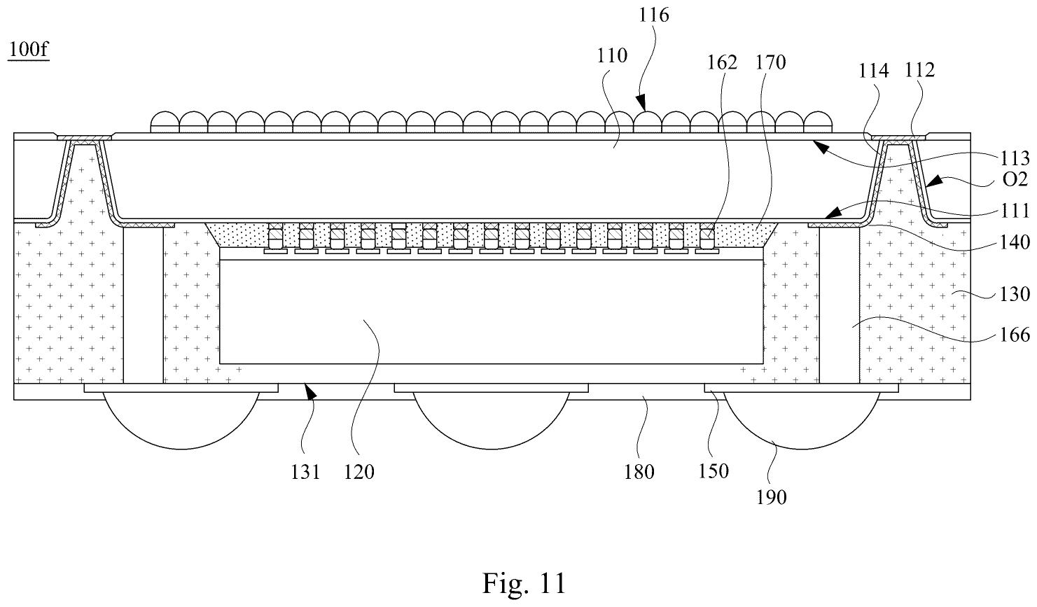

As shown in FIG. 11, the difference between this embodiment and the embodiment of FIG. 7 is that the mother chip 110 of the chip package 100f has the through hole O2 that is tapered from the second surface 113 of the mother chip 110 to the conductive pad 112. Moreover, the second surface 113 of the mother chip 110 has the image sensing region 116.

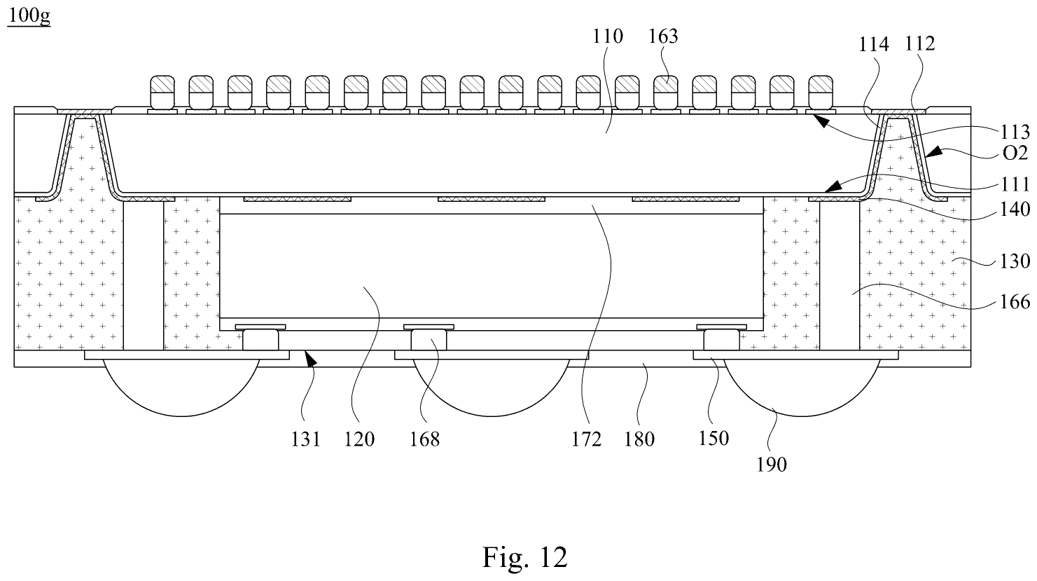

As shown in FIG. 12, the difference between this embodiment and the embodiment of FIG. 10 is that the chip package 100g has the micro bump 163 located on the second surface 113 of the mother chip 110.

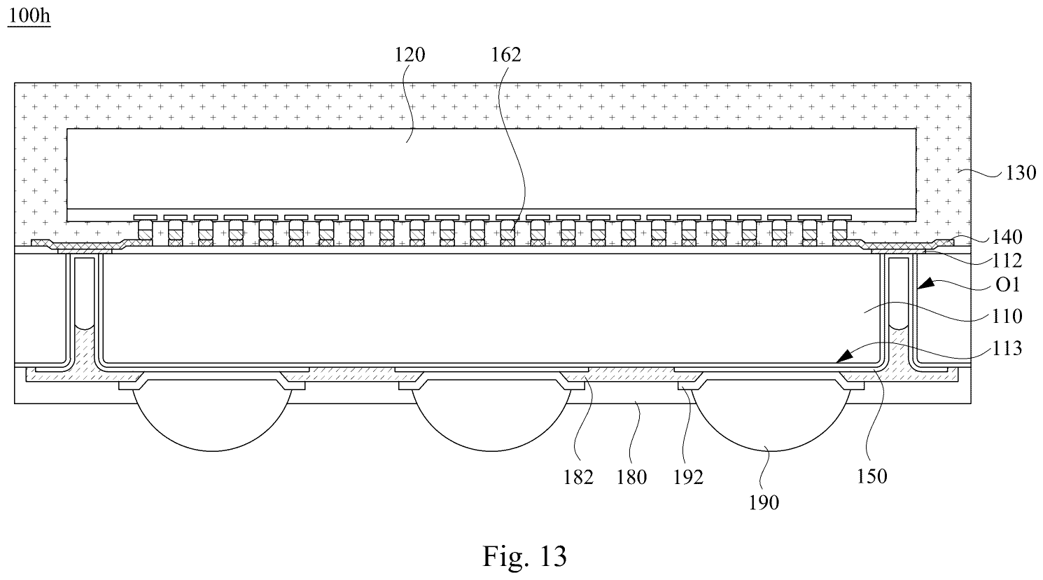

As shown in FIG. 13, the difference between this embodiment and the embodiment of FIG. 1 is that the chip package 100h further includes a second passivation layer 182 located between the second redistribution layer 150 and the first passivation layer 180. Moreover, the molding compound 130 of the chip package 100h surrounds the micro bump 162. In this embodiment, the chip package 100h further includes a metal layer 192 between the second redistribution layer 150 and the conductive structure 190. The material of the second passivation layer 182 may include polyimide (PI).

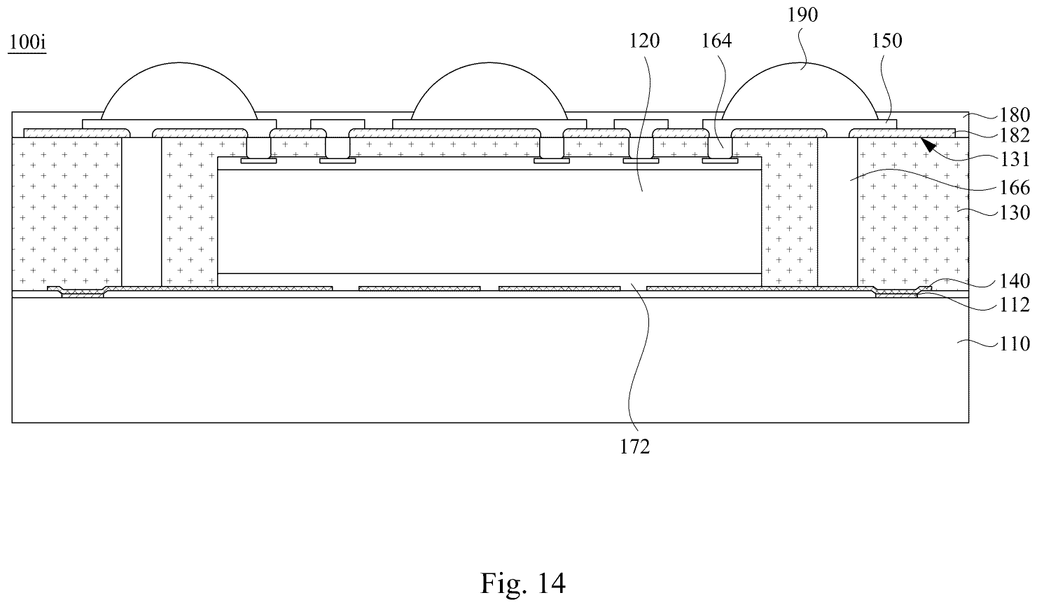

As shown in FIG. 14, the difference between this embodiment and the embodiment of FIG. 3 is that the chip package 100i further includes the second passivation layer 182 located between the second redistribution layer 150 and the surface 131 of the molding compound 130.

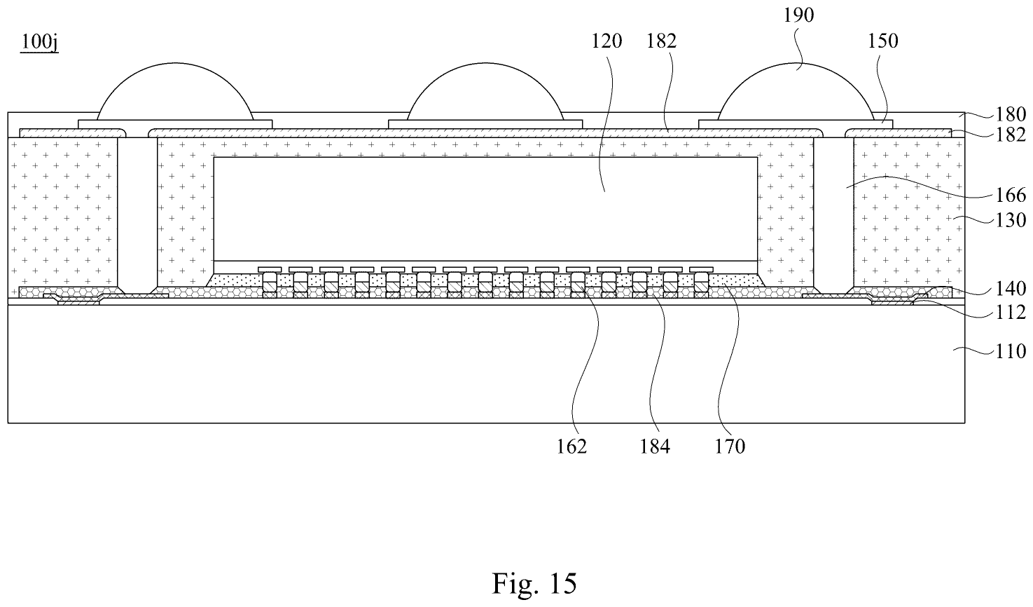

As shown in FIG. 15, the difference between this embodiment and the embodiment of FIG. 14 is that the chip package 100j further includes the underfill layer 170 and a passivation layer 184. The underfill layer 170 is located between the daughter chip 120 and the mother chip 110, and the underfill layer 170 surrounds the micro bump 162 of the daughter chip 120. The passivation layer 184 is located between the underfill layer 170 and the mother chip 110, and covers the first redistribution layer 140. The material of the passivation layer 184 may include polyimide (PI).

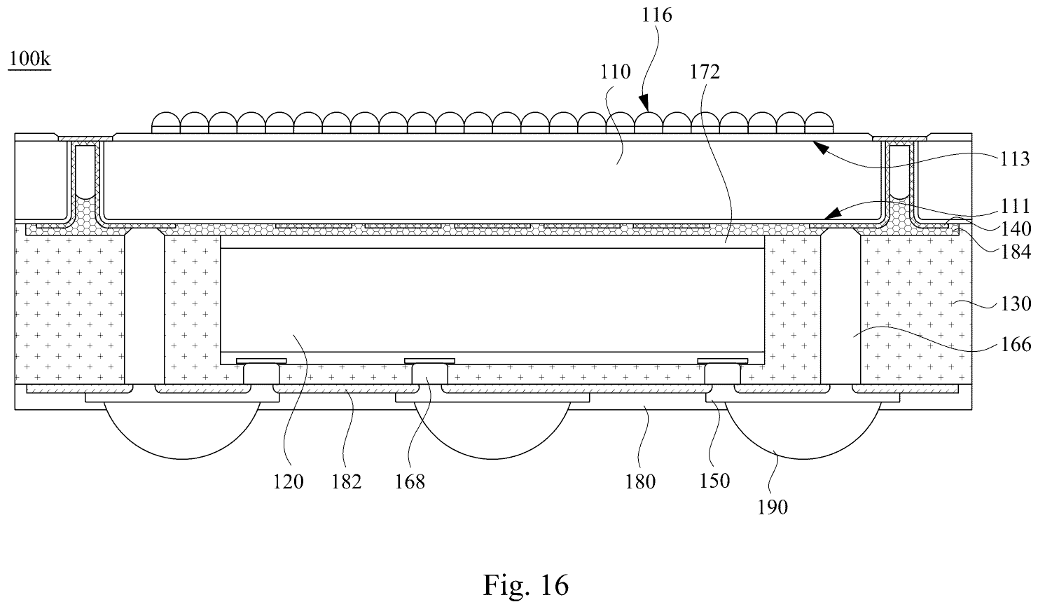

As shown in FIG. 16, the difference between this embodiment and the embodiment of FIG. 5 is that the chip package 100k further includes the second passivation layer 182 and the passivation layer 184. The second passivation layer 182 is located between the second redistribution layer 150 and the first passivation layer 180. The passivation layer 184 is located between the die attach film 172 and the mother chip 110 and covers the first redistribution layer 140. In addition, the chip package 100k further includes the conductive pillar 168 electrically connected to the daughter chip 120 and the second redistribution layer 150, and the conductive pillar 168 is surrounded by the molding compound 130.

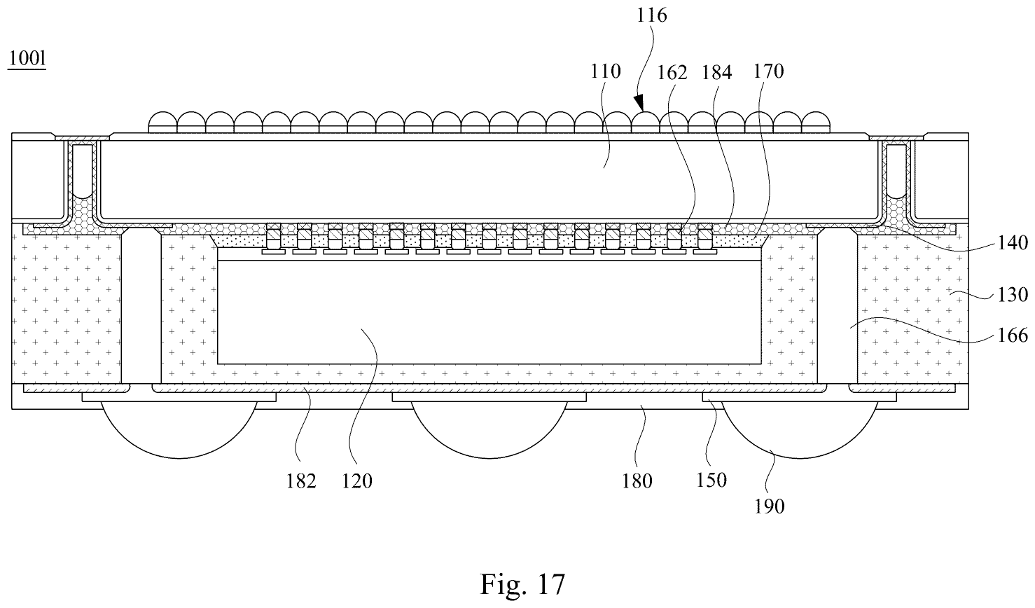

As shown in FIG. 17, the difference between this embodiment and the embodiment of FIG. 16 is that the chip package 1001 further includes the underfill layer 170 located between the daughter chip 120 and the mother chip 110. Furthermore, the underfill layer 170 surrounds the micro bump 162 of the daughter chip 120.

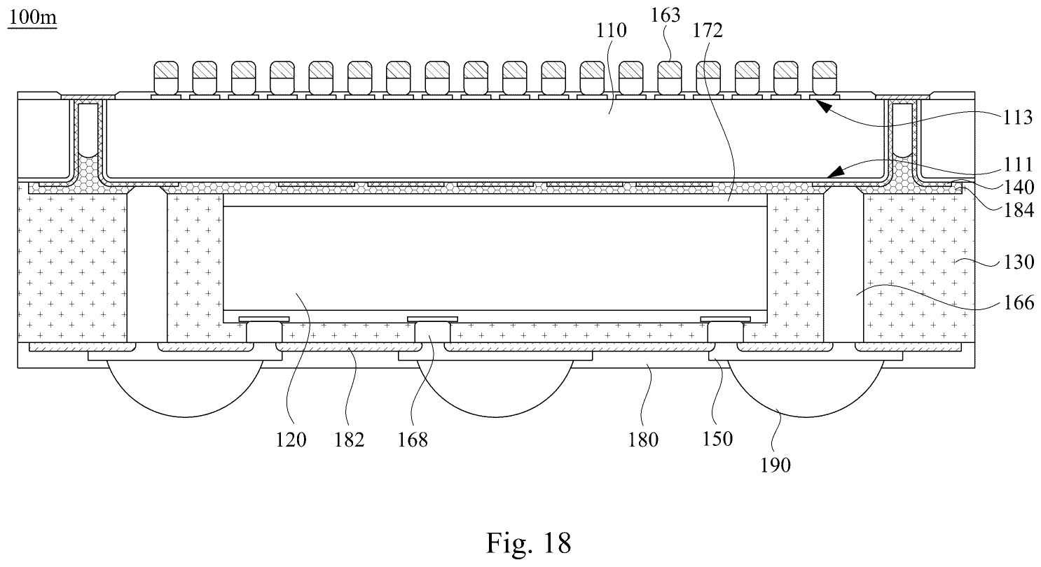

As shown in FIG. 18, the difference between this embodiment and the embodiment of FIG. 16 is that the chip package 100m further has the micro bump 163 located on the second surface 113 of the mother chip 110.

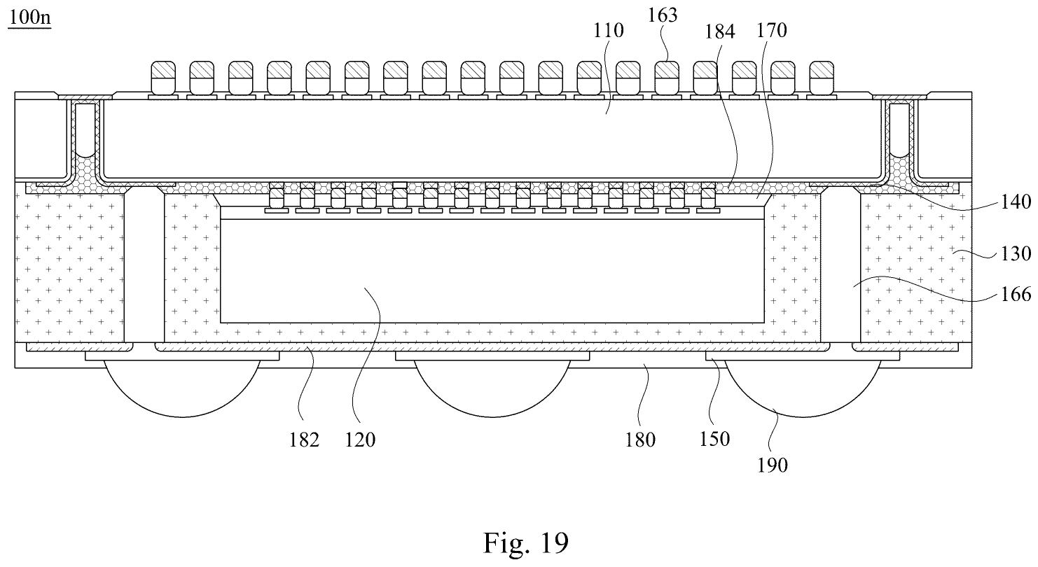

As shown in FIG. 19, the difference between this embodiment and the embodiment of FIG. 17 is that the chip package 100n further has the micro bump 163 located on the second surface 113 of the mother chip 110.

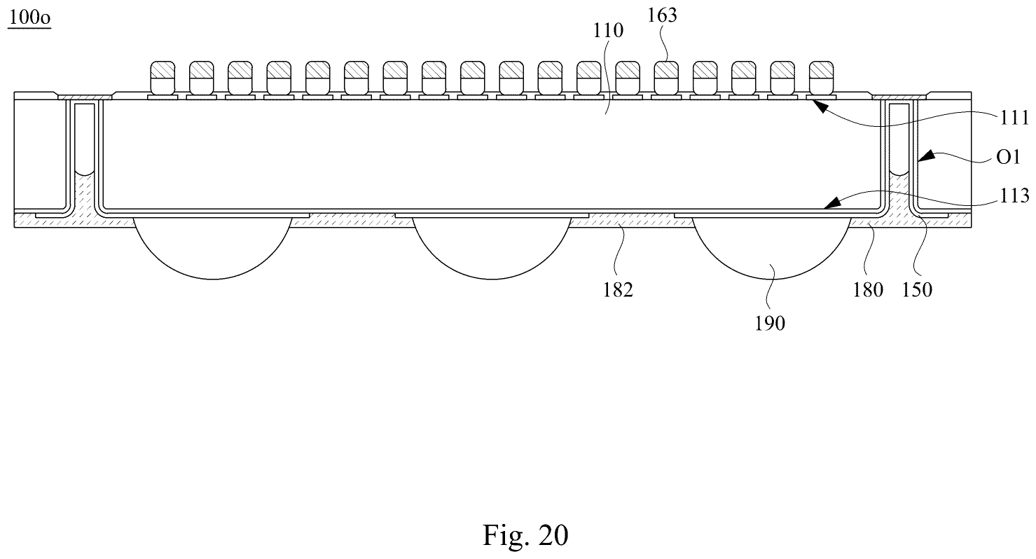

As shown in FIG. 20, the chip package 1000 includes the mother chip 110, the micro bump 163, the second redistribution layer 150, the first passivation layer 180, and the conductive structure 190.

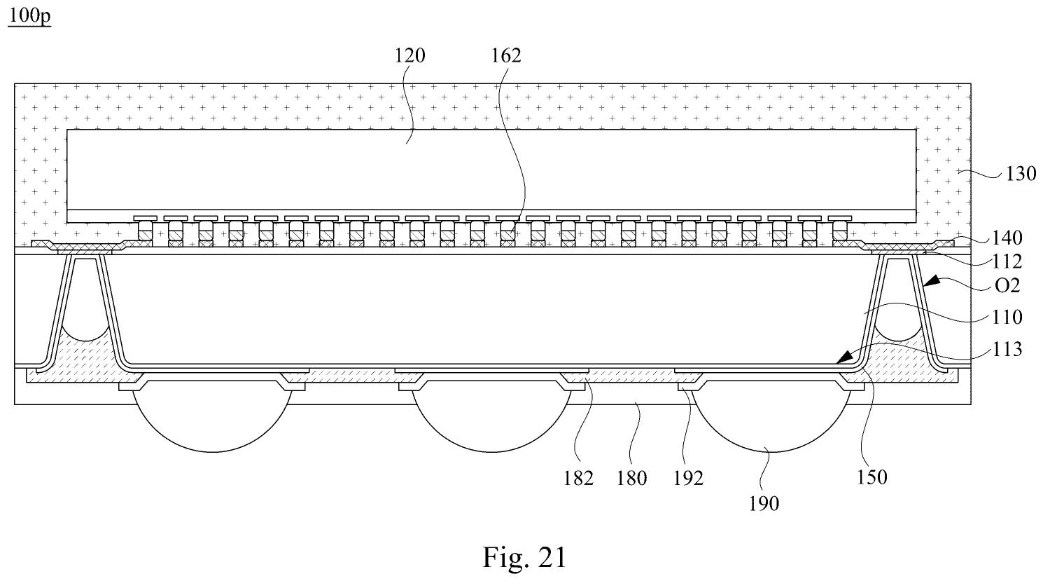

As shown in FIG. 21, the difference between this embodiment and the embodiment of FIG. 13 is that the mother chip 110 of the chip package 100p has the through hole O2 that is tapered from the second surface 113 of the mother chip 110 to the conductive pad 112.

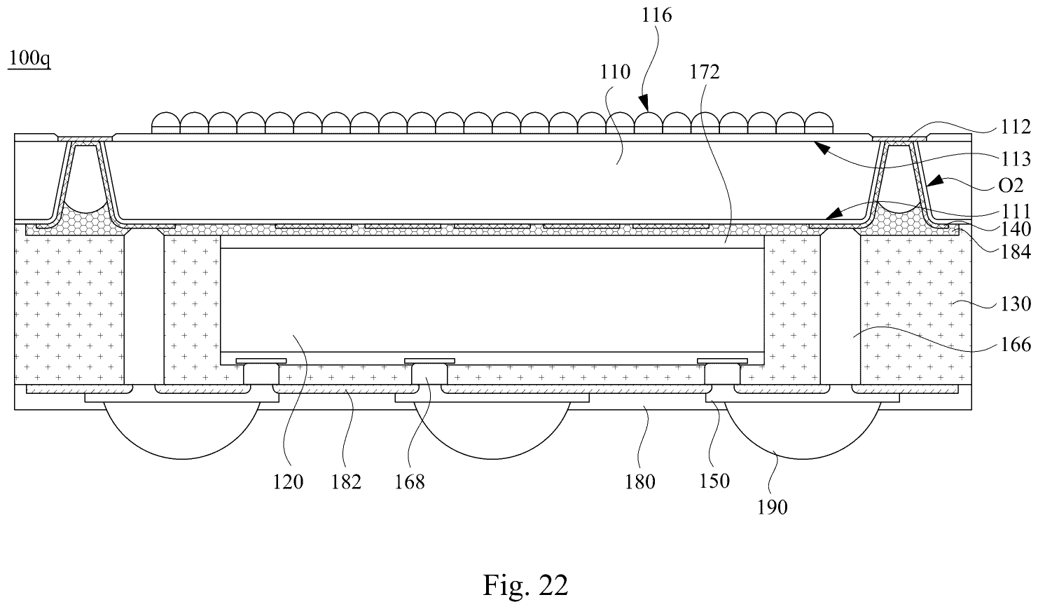

As shown in FIG. 22, the difference between this embodiment and the embodiment of FIG. 16 is that the mother chip 110 of the chip package 100q has the through hole O2 that is tapered from the first surface 111 of the mother chip 110 to the conductive pad 112.

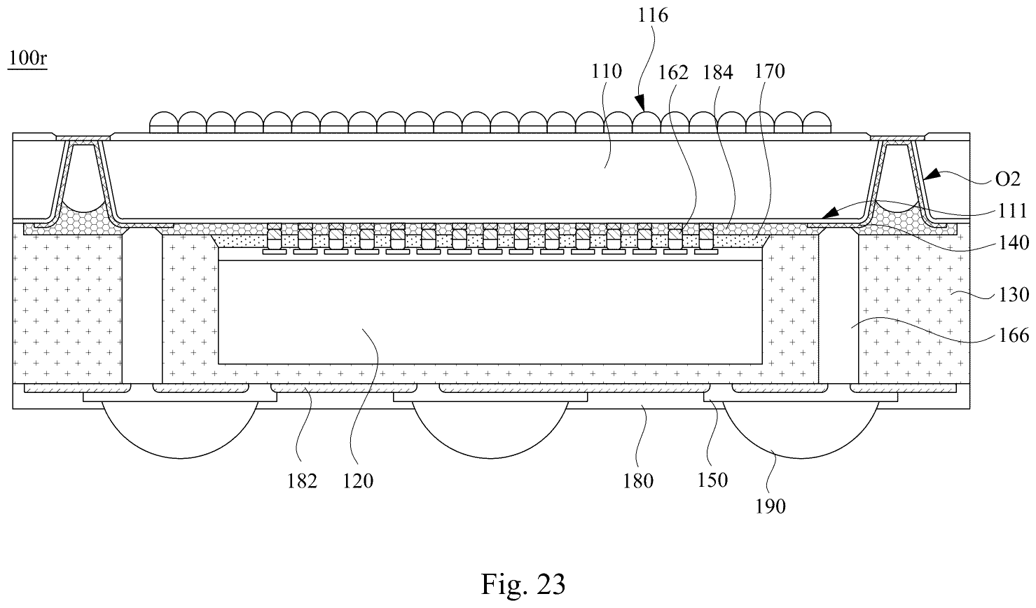

As shown in FIG. 23, the difference between this embodiment and the embodiment of FIG. 17 is that the mother chip 110 of the chip package 100r has the through hole O2 that is tapered from the first surface 111 of the mother chip 110 to the conductive pad 112.

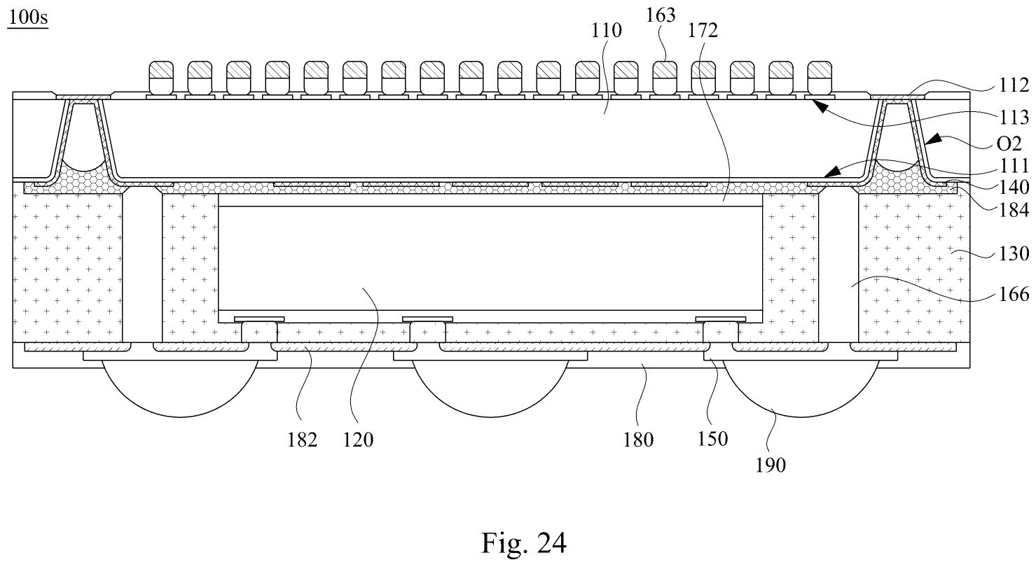

As shown in FIG. 24, the difference between this embodiment and the embodiment of FIG. 22 is that the chip package 100s further has the micro bump 163 located on the second surface 113 of the mother chip 110.

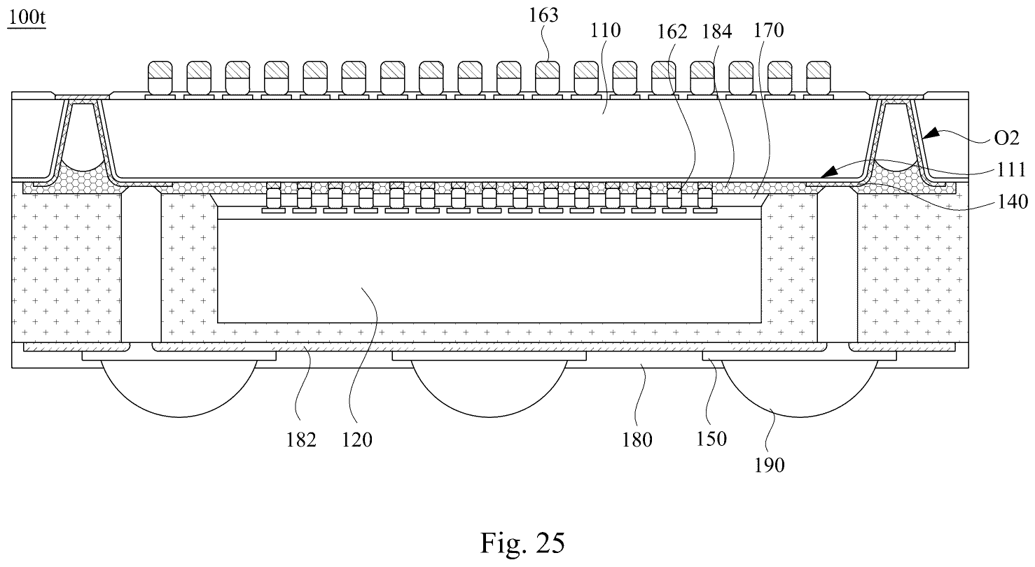

As shown in FIG. 25, the difference between this embodiment and the embodiment of FIG. 23 is that the chip package 100t further has the micro bump 163 located on the second surface 113 of the mother chip 110.

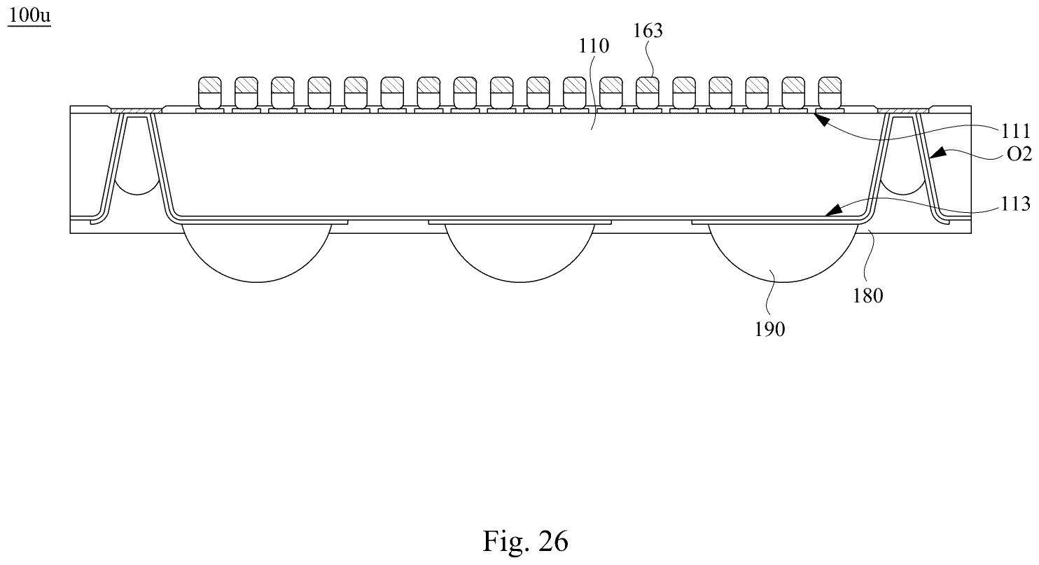

As shown in FIG. 26, the difference between this embodiment and the embodiment of FIG. 20 is that the mother chip 110 of the chip package 100u has the through hole O2 that is tapered from the second surface 113 of the mother chip 110 to the conductive pad 112.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a mother chip;
a daughter chip located on a first surface of the mother chip;
a molding compound covering the mother chip and the daughter chip, wherein the daughter chip is surrounded by the molding compound;
a first redistribution layer located on the first surface of the mother chip and covered by the molding compound; and
a second redistribution layer electrically connected to the first redistribution layer and located on one of a second surface of the mother chip opposite to the first surface and a surface of the molding compound that faces away from the mother chip and the daughter chip, wherein one of the first redistribution layer and the second redistribution layer is electrically connected to the daughter chip, and the other of the first redistribution layer and the second redistribution layer is electrically connected to the mother chip.

2. The chip package of claim 1, wherein the daughter chip has a micro bump located on the first surface of the mother chip and electrically connected to the first redistribution layer.

3. The chip package of claim 2, further comprising:
an underfill layer located between the daughter chip and the mother chip and surrounding the micro bump.

4. The chip package of claim 3, further comprising:
a passivation layer located between the underfill layer and the mother chip.

5. The chip package of claim 1, further comprising:
a conductive pillar located on the first redistribution layer and surrounded by the molding compound, wherein two ends of the conductive pillar are respectively in electrical contact with the first redistribution layer and the second redistribution layer.

6. The chip package of claim 1, further comprising:
a conductive pillar located on a surface of the daughter chip facing away from the mother chip, and electrically connected to the second redistribution layer and surrounded by the molding compound.

7. The chip package of claim 1, wherein the mother chip has a through hole and a conductive pad in the through hole, and the second redistribution layer extends into the through hole and is in electrical contact with the conductive pad.

8. The chip package of claim 7, wherein the through hole is tapered from the second surface of the mother chip to the conductive pad.

9. The chip package of claim 7, wherein the through hole is tapered from the first surface of the mother chip to the conductive pad.

10. The chip package of claim 1, further comprising:
a die attach film located between the daughter chip and the mother chip.

11. The chip package of claim 10, further comprising:
a passivation layer located between the die attach film and the mother chip.

12. The chip package of claim 1, further comprising:
a first passivation layer located on the second redistribution layer and the second surface of the mother chip.

13. The chip package of claim 12, further comprising:
a conductive structure located on the second redistribution layer and in the first passivation layer.

14. The chip package of claim 12, further comprising:
a second passivation layer located between the second redistribution layer and the first passivation layer.

15. The chip package of claim 1, further comprising:
a first passivation layer located on the second redistribution layer and the surface of the molding compound that faces away from the mother chip and the daughter chip.

16. The chip package of claim 15, further comprising:
a conductive structure located on the second redistribution layer and in the first passivation layer.

17. The chip package of claim 16, further comprising:
a second passivation layer located between the second redistribution layer and the surface of the molding compound.

18. The chip package of claim 1, wherein the second surface of the mother chip has an image sensing region.

19. The chip package of claim 1, further comprising:
a micro bump located on the second surface of the mother chip.

20. A manufacturing method of a chip package, comprising:
forming a first redistribution layer on a first surface of a mother chip;
disposing a daughter chip on the first surface of the mother chip;
forming a molding compound covering the mother chip and the daughter chip, wherein the daughter chip is surrounded by the molding compound, and the first redistribution layer is covered by the molding compound; and
forming a second redistribution layer electrically connected to the first redistribution layer and on one of a second surface of the mother chip opposite to the first surface and a surface of the molding compound that faces away from the mother chip and the daughter chip, wherein one of the first redistribution layer and the second redistribution layer is electrically connected to the daughter chip, and the other of the first redistribution layer and the second redistribution layer is electrically connected to the mother chip.
